(19) United States
(12) Patent Application Publication
(10) Pub. No.: US 2005/0040818 A1
(43) Pub. Date: Feb. 24, 2005

(54) Magnetic field sensor

(76) Inventors: Phil MacPhail, Cambridge (GB); Anatoli Pukhovski, Nepean (CA)

Correspondence Address: KENYON & KENYON, 1500 K STREET, N.W., SUITE 700, WASHINGTON, DC, 20005, US

(21) Appl. No.: 10/644,786

(22) Filed: Aug. 21, 2003

(51) Int. Cl. G01R 33/04; G01C 17/02

(52) U.S. Cl. 324/255; 33/319; 33/355 R

(57) ABSTRACT

An electronic compass featuring low power consumption and small die space requirements is disclosed. The compass features an electronic circuit that provides a controlled flow of electrical current to a coil. Additionally, the circuit monitors the coil to determine when the coil becomes magnetically saturated. The duration of the magnetic saturation is monitored to determine the presence and direction of an external magnetic field.

### FIELD OF THE INVENTION

The invention relates to the driving of an electromagnetic coil supporting a core. More specifically, the invention relates to a system for driving an electromagnetic coil that automatically senses when the electromagnetic core becomes saturated.

### BACKGROUND OF THE INVENTION

The prior art teaches simple electrical circuits featuring electromagnetic coils that are useable as an electronic compass. An alternating current is applied to a coil such that a core disposed within the coil alternates between a first magnetically saturated state and a second magnetically saturated state directionally opposite the first magnetically saturated state. The presence of external magnetic fields affects the duration of magnetic saturation. Specifically, when an external magnetic field provides magnetic flux in a same direction as the electrically induced magnetic field of the core, the magnetic fields sum constructively. Thus, when the fields are adding constructively, the current associated with achieving magnetic saturation is minimized. Conversely, when the flux from the external magnetic field is opposite the flux provided by the electrically induced magnetic field of the core the current associated with achieving magnetic saturation is maximized. When the coil is provided, for example, with a triangular wave pulsed current signal a periodic change between the two magnetically saturated states occurs. The durations of the two saturation states are compared with the predetermined pulsed signal. Thus, the relative timing between the two saturated states is measured to determine the magnitude and sign of an external magnetic field. When properly designed and produced, such a device is sufficiently accurate to measure the orientation of Earth's magnetic field relative to the coil.

These devices have a variety of applications included direction sensors for navigation equipment, metal detectors, and magnetic field sensors.

It would be beneficial to provide a simple, robust and inexpensive system that accurately senses external magnetic fields and is sufficiently compact to be suitable for integration in a variety of portable consumer electronics devices.

### SUMMARY OF THE INVENTION

The invention provides an electronic compass comprising:

a coil having a pair of contacts, the coil for alternating between a first magnetically saturated state and a second magnetically saturated state in response to a current signal applied to the contacts and an external magnetic field, the second magnetically saturated state being opposite the first magnetically saturated state; and,

an integrated circuit electrically coupled to the contacts of the coil, the integrated circuit for providing a time varying current signal to the coil, the integrated circuit also for monitoring a voltage potential between the contacts.

Further the invention teaches a method of determining a direction of the Earth's magnetic field comprising:

using an integrated circuit to provide a current signal to a coil via a pair of contacts;

monitoring a voltage potential between the pair of contacts;

determining a first period of time associated with a first electromagnetic saturation of the coil;

determining a second period of time associated with a second electromagnetic saturation of the coil, the second electromagnetic saturation of the coil being directionally opposite to the first electromagnetic saturation;

determining a direction based upon characteristics of the current signal, the first period of time and the second period of time.

### BRIEF DESCRIPTION OF THE DRAWINGS

The invention is now described with reference to the figures in which:

FIG. 1 is a prior art electrical circuit diagram of a core with multiple windings having a resistor in series with one of the windings;

FIG. 2 is a prior art electrical circuit diagram of a coil in series with two resistors according to the prior art;

FIG. 3 is a prior art electrical circuit diagram of an assembly with two windings and a common core;

FIG. 4 is an electrical circuit diagram of coil according to the invention;

FIG. 5 is a schematic diagram of a circuit used to interpret sensor data;

FIG. 6 is a graph indicating a response time of the coil of FIG. 3 in a first orientation; and,

FIG. 7 is a graph indicating a response time of the coil of FIG. 3 in a second orientation.

### DETAILED DESCRIPTION OF THE INVENTION

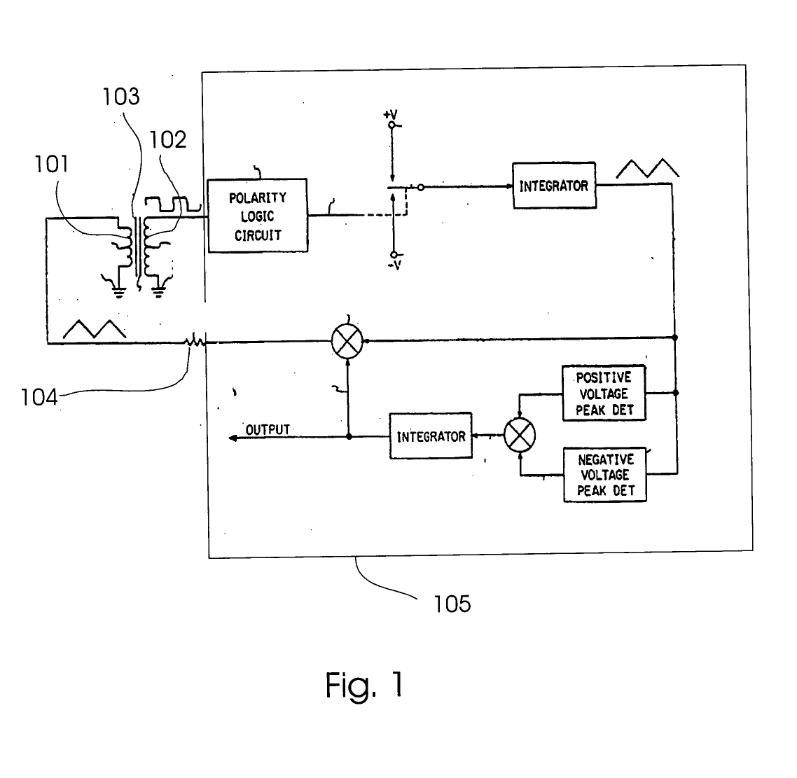

In U.S. Pat. No. 4,300,095 by Rhodes, issued Nov. 10, 1981, a magnetic field detection apparatus is described. Referring to FIG. 1, a circuit diagram of the Rhodes prior art device is shown. The diagram clearly shows a coil 110, a resistor 104, and a variety of circuitry 105. The coil 110 comprises a first winding 101, a second winding 102 and a core 103. In use, the circuitry provides a triangular wave voltage signal to the resistor 104. The resistor 104 has sufficient resistance that a current signal provided to the first winding 101 is proportional to the voltage signal. The circuitry 105 includes a voltage sensor for monitoring a voltage signal provided from the second winding 102. This voltage signal is used to determine the orientation of the core 103 relative to an external magnetic field.

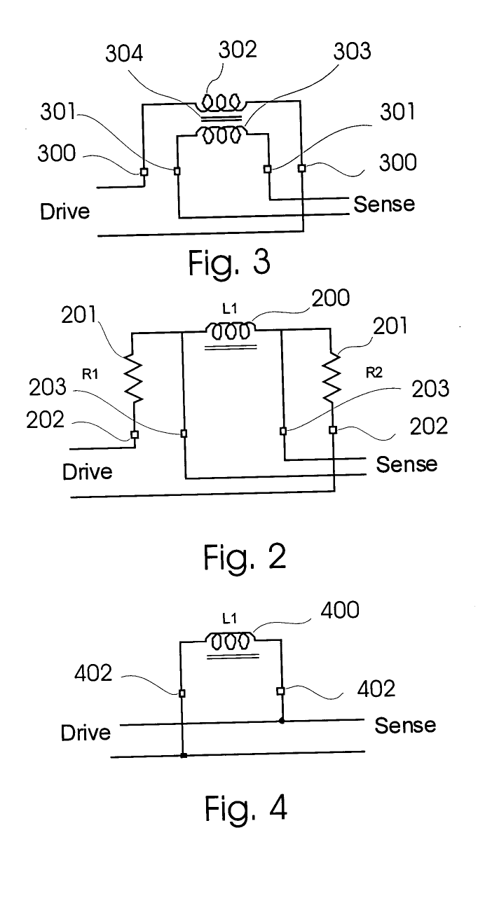

Referring to FIG. 2 another prior art circuit diagram is shown. This diagram includes a coil 200, a pair of resistors 201, a set of drive contacts 202, and a set of sensor contacts 203. In use, a voltage signal is applied to the drive contacts 202. The voltage signal is periodically pulsed resulting in a pulsed current signal having a same period as the voltage signal. A voltage sensor is attached to the sensor contacts 203. The voltage sensor provides data indicative of a saturation state of the core associated with the coil 200.

The prior art devices described with reference to FIG. 1 and FIG. 2 incorporate circuits featuring at least one resistor electrically coupled in series with a coil. The coil and resistor are then provided a voltage signal that provides sufficient current to the coil to produce the desired magnetic saturation of a core. It will be apparent to one of skill in the art that providing a consistently alternating voltage signal for use with the prior art of FIG. 1 and FIG. 2 is easily achieved with inexpensive bulk components. A person of skill in the art will also be aware that it is highly advantageous to use an integrated circuit (IC) to monitor a voltage signal for the purposes of determining duration data of the voltage signal. Thus, in the prior art circuit of FIG. 2, it would be expected that a bulk components circuit provides power to the coil 200 via the drive contacts 202 while an IC voltage sensor monitors the sensor contacts 203.

Referring to FIG. 3, a prior art circuit diagram featuring multiple windings is shown. The diagram includes drive contacts 300, sensor contacts 301, a drive coil 302, a sensor coil 303 and a core 304. In use, an electrical signal is applied to the drive contacts 300. Since the electrical signal is applied directly to the drive contacts 300 absent a substantial resistance a person of skill in the art will conclude that the electric signal is a current signal. As a person of skill in the art of electronic circuits will be aware, such a current signal is conveniently provided using an integrated circuit. In order to determine the magnetic saturation state of the core 304 a voltage sensor is electrically coupled to the sensor contacts 301. Such a voltage sensor is conveniently provided as an integrated circuit. Clearly, a same IC having four electrical contacts is optionally used to provide a drive signal to the drive contacts 300 and receive sensor signals from the sensor contacts 301.

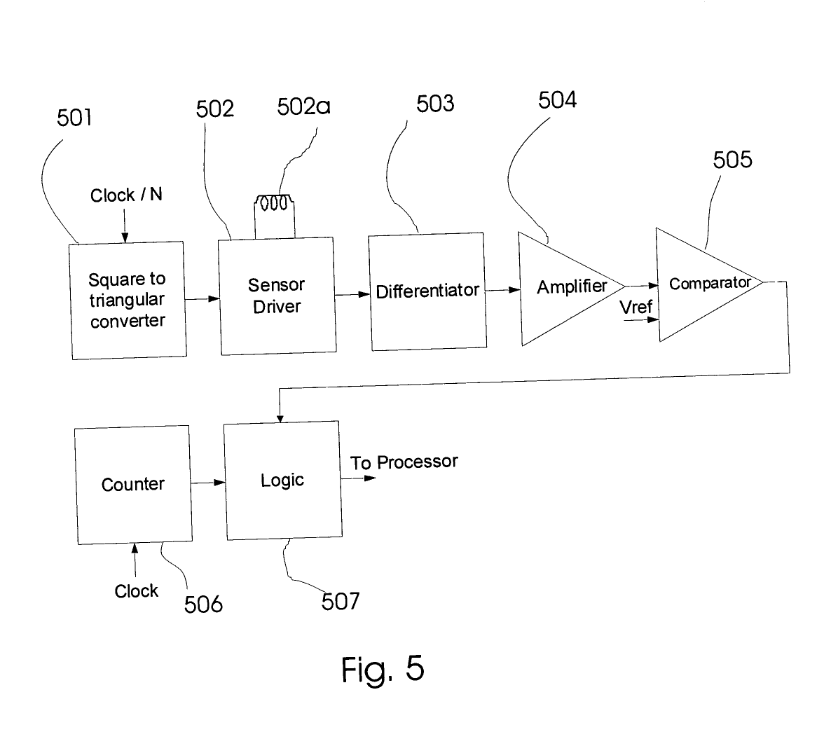

Referring to FIG. 4, an electronic compass circuit diagram according to a first embodiment of the invention is shown. The device includes: a coil 400, a pair of contacts 402 and a core 403. In use, an external circuit (not shown) provides a controlled current signal to the contacts 402. The current signal has a predetermined cyclical behaviour such that when the current signal is applied, absent an external magnetic field, the core 403 alternates between a first magnetically saturated state and a second opposite magnetically saturated state. The electrical circuit also monitors the voltage across the coil 400 and thereby provides data used to determine the duration of saturation of the core 403 in each of the magnetically saturated states. By comparing the difference between the intervals in which the coil is magnetically saturated and the predetermined cyclic current, orientation data relating to an angle between external magnetic field and the coil is determined. Unlike the prior art coil circuits of FIG. 1, FIG. 2 and FIG. 3, only two electrical contacts are used between the circuit and the coil. Since only two electrical contacts are used and both the drive circuit and the sensor circuit are provided by integrated circuits an electronic compass designed according to this first embodiment of the invention is optionally very compact and uses a minimum of board space. The external circuit is described with reference to FIG. 5 hereinbelow.

In order to provide more compact inductors a variety of research has been provided regarding planar fluxgate devices. Such a fluxgate is suitable for sensing external magnetic fields as described by Dezurai, Belloy, Gilbert and Martin in “New Hybrid Technology for Planar Fluxgate Sensor Fabrication”, IEEE Transactions on magnetics, Vol. 35, No. 4 Jul. 1999, p. 2111 to 2117 and by Kawahito, Maier, Schneider, Zimmerman and Baltes in “A 2-D CMOS Microfluxgate Sensor System for Digital Detection of Weak Magnetic Field”, IEEE Journal of Solid-state circuits, Vol. 34, no. 12, December 1999, p. 1843 to 1851. Indeed the fluxgate sensor devices function in a manner highly analogous to a conventional coil inductor. Despite these advances, such fluxgates are often difficult to manufacture and consequently, integrated circuits featuring such fluxgates are often quite costly. It will be apparent to one of skill in the art that an embodiment of the invention featuring a fluxgate is able to support the use of a simple fluxgate, analogous to the coil shown in FIG. 4. Advantageously, using such an embodiment of the invention, the sensor circuitry and the driver circuitry are optionally provided on the same integrated circuit. Thus, a considerable amount of die area need not be allocated for a bulk component inductor and contacts for the bulk component inductors.

Clearly, in many applications, providing angular orientation data relative to one axis is insufficient to provide the desired information. Thus, in a second embodiment of the invention a first and a second device according to the first embodiment of the invention are provided. The second device is disposed at a predetermined angle to the first thereby providing data corresponding to a second axis. In this way, data associated with two different orientation angles is provided. It is suggested that the second device be disposed at a right angle to the first however this need not be the case. Optionally, a third sensor is provided, preferably at a right angle to the other two sensors, in order to provide magnetic field data regarding a third axis.

Referring to FIG. 5, a block diagram corresponding to an electrical circuit for use with the first embodiment of the invention is shown. The circuit 500 includes: a square to triangular wave converter (ST converter) 501, a sensor driver 502 with a coil 502a, a differentiator 503, an amplifier 504, a comparator 505, a counter 506 and a logic circuit 507. In use, the ST converter 501 receives a square wave voltage signal. The ST converter 501 then provides a triangular wave voltage signal to an ST converter output port. The triangular voltage signal propagates from the output port of the ST converter to an input port of the sensor driver 502. A corresponding triangular wave voltage signal is provided to the coil 502a. This voltage signal is sufficient to cause periodic magnetic saturation in the coil 502a. The presence of an external magnetic field, such as the magnetic field of the earth, affects the duration of the magnetic saturation of the coil 502a. The sensor driver 502 provides a voltage feedback signal that is indicative of coil saturation to the sensor driver output port. The voltage feedback signal propagates from the sensor driver output port to the differentiator input port where it is received by the differentiator 503. The differentiator 503 provides a differentiated signal indicative of the derivative of the voltage feedback signal to a differentiator output port. The differentiated signal propagates to an input port of the amplifier 504. The amplifier 504 receives the differentiated signal, amplifies the differentiated signal, and provides an amplified signal to an amplifier output port. The amplified signal propagates from the amplifier output port to a first input port of a comparator 505. Additionally, a predetermined reference voltage signal is provided to a second input port of the comparator 505. The comparator 505 determines which of the amplified signal and the reference voltage has a higher voltage and provides a comparator signal to a comparator output port. The comparator signal propagates to a first input port of the logic circuit 507. A high frequency clock signal is provided to a second input port of the logic circuit 507. The logic circuit is designed to count a number of high frequency pulses associated with the high frequency clock signal corresponding to the saturated and unsaturated states of the coil. A comparison of the number of pulses is then used to obtain data regarding an external magnetic field. In a region in which the local strength of the external magnetic field is known then an orientation of the magnetic field is optionally determined. Thus, this circuit is useful in determining the orientation of the coil relative to magnetic field of the earth proximate the coil.

Since a circuit according to the block diagram of FIG. 5 has very simple connections between the sensor driver 502 and the coil 502a a relatively inexpensive coil is used to produce highly accurate readings. Additionally, as fewer connections are used in the device according to the invention than in the prior art, the device uses substantially less die area. These advantages are particularly beneficial for electronic compasses that rely on a plurality of coils to determine the orientation of the magnetic field of the earth.

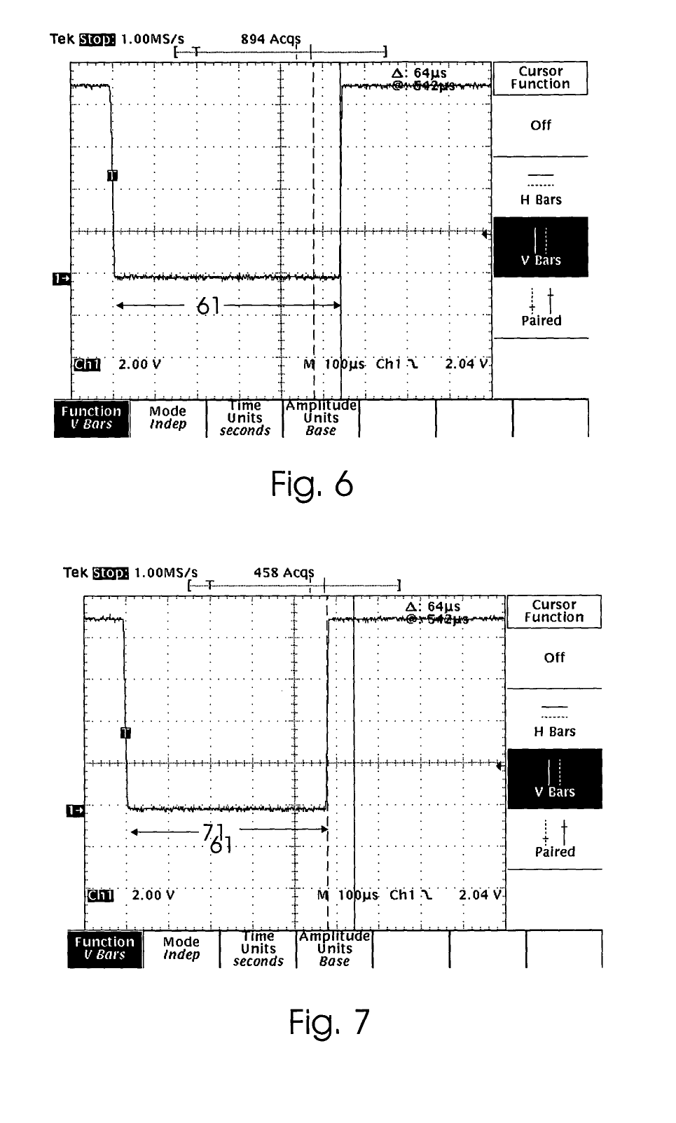

Experimental results from a system according to the first embodiment of the invention are provided in FIG. 6 and FIG. 7. This system utilizes a signal having a frequency of 1 kHz ±3%. Referring to FIG. 6, an electrical signal is shown. The electrical signal is provided from a coil in which a core associated with the coil is locally oriented to receive a maximum amount of magnetic flux from the magnetic field of the Earth. The electrical signal has a pulse length 61, indicating the duration of a magnetically saturated state of a coil. Referring to FIG. 7, a second electrical signal is shown. In order to generate the electrical signal of FIG. 7 the core of the apparatus is rotated to a second orientation opposite the orientation of the core associated with FIG. 6. FIG. 7 clearly shows a pulse length 71. A difference in the pulse length 61 and the pulse length 71 indicates a difference in time associated with the magnetic saturation state of the core as a direction of a current propagating through the coil is reversed. As described hereinabove, the electromagnetic field generated by the coil will interact with external magnetic fields to cause magnetic saturation. FIG. 6 and FIG. 7 clearly show that the presence of the external magnetic field affects the time at which the core changes saturation states. The difference in pulse lengths 61 and 71 was found to be 64 μs. Using a 20 MHz high frequency clock to measure the duration of pulses from the electronic compass circuit an electronic compass having accuracy of 1° is provided. This accuracy is felt to be more than adequate for most hand held devices.

Numerous other embodiments of the invention will be apparent to one of skill in the art.

1. An electronic compass comprising:
a coil comprising a core and a pair of contacts, the core for alternating between a first magnetically saturated state and a second magnetically saturated state in response to a time-varying current signal applied to the contacts and an external magnetic field, the second magnetically saturated state having an opposite polarity to the first magnetically saturated state; and,
an integrated circuit comprising two contacts and disposed on a substrate, the contacts of the integrated circuit electrically coupled to the contacts of the coil, the two contacts of the integrated circuit both for providing the time-varying current signal and for receiving a time-varying voltage signal, the time-varying voltage signal having a duty cycle dependant upon an orientation of the coil relative to the external magnetic field.

2. An electronic compass according to claim 1, wherein the time-varying current signal is a triangular wave current signal.

3. An electronic compass according to claim 1, wherein the integrated circuit comprises: square wave to triangular wave converter.

4. An electronic compass according to claim 1, wherein the integrated circuit comprises: a triangular wave generator.

5. An electronic compass according to claim 1, wherein the coil is a component integrated on a second substrate.

6. An electronic compass according to claim 1, wherein the coil is integrated on a same substrate as the integrated circuit.

7. An electronic compass according to claim 1, comprising a second coil, the second coil comprising a second core and a second pair of contacts, the second core for alternating between a third magnetically saturated state and a fourth magnetically saturated state in response to a time-varying current signal applied to the second pair of contacts and the external magnetic field, the fourth magnetically saturated state having an opposite polarity to the third magnetically saturated state, the second coil disposed at a substantially non-zero angle relative to the first coil.

8. An electronic compass according to claim 7, comprising a third coil, the third coil comprising a third core and a third pair of contacts, the third core for alternating between a fifth magnetically saturated state and a sixth magnetically saturated state in response to a time-varying current signal applied to the third pair of contacts and the external magnetic field, the sixth magnetically saturated state having an opposite polarity to the fifth magnetically saturated state, the third coil disposed at a substantially non-zero angle relative to both the first coil and the second coil.

9. A method of determining a direction of the Earth's magnetic field comprising:
using an integrated circuit to provide a current signal to a coil via a pair of contacts, the coil comprising a core;
monitoring a voltage potential between the pair of contacts;
determining a duty cycle associated with a first electromagnetic saturation of the core, and a second electromagnetic saturation of the core, the second electromagnetic saturation of the core having an opposite polarity to the first electromagnetic saturation; and,
determining a direction based upon characteristics of the current signal, and the duty cycle.

10. A method according to claim 9, wherein in the step of using an integrated circuit, the integrated circuit provides a triangular output signal.

11. A method according to claim 9, wherein in the step of monitoring a voltage potential the voltage potential is monitored using an integrated circuit.

12. A method according to claim 9, wherein in the step of monitoring a voltage potential the voltage potential is monitored using the integrated circuit described in the step of using an integrated circuit.

13. An electronic component comprising:
an integrated circuit comprising two contacts and disposed on a substrate, the two contacts of the integrated circuit for being electrically coupled a pair of contacts of a coil, the two contacts of the integrated circuit both for providing a time-varying current signal and for receiving a time-varying voltage signal, the integrate circuit for use in determining an orientation relative to an external magnetic field.

14. An electronic component according to claim 13, wherein the time-varying current signal is a triangular wave current signal.

15. An electronic component according to claim 13, wherein the integrated circuit comprises: square wave to triangular wave converter.

16. An electronic component according to claim 13, wherein the integrated circuit comprises: a triangular wave generator.

17. An electronic component according to claim 13, comprising the coil, wherein the coil is a component integrated on a second substrate.

18. An electronic component according to claim 13, comprising the coil, wherein the coil is integrated on a same substrate as the integrated circuit.

19. An electronic component according to claim 13, comprising the coil and a second coil, the second coil comprising a second core and a second pair of contacts, the second core for alternating between a third magnetically saturated state and a fourth magnetically saturated state in response to a time-varying current signal applied to the second pair of contacts and the external magnetic field, the fourth magnetically saturated state having an opposite polarity to the third magnetically saturated state, the second coil disposed at a substantially non-zero angle relative to the first coil.

20. An electronic component according to claim 19, comprising a third coil, the third coil comprising a third core and a third pair of contacts, the third core for alternating between a fifth magnetically saturated state and a sixth magnetically saturated state in response to a time-varying current signal applied to the third pair of contacts and the external magnetic field, the sixth magnetically saturated state having an opposite polarity to the fifth magnetically saturated state, the third coil disposed at a substantially non-zero angle relative to both the first coil and the second coil.
